(19) United States
(12) Patent Application Publication
(10) Pub. No.: US 2026/0205146 A1
(43) Pub. Date: Jul. 16, 2026

(54) Wireless Circuitry with Weighted Envelope Tracking Delay

(71) Applicant: Apple Inc., Cupertino, CA (US)

(72) Inventors: Pedro Mirassol Tomé, Munich (DE); Francesco Lombardo, Haar (DE); Benjamin Laemmle, Freising (DE); Florin-Gabriel Pascaru, Unterhaching (DE)

(21) Appl. No.: 19/018,598

(22) Filed: Jan. 13, 2025

(51) Int. Cl. H04B 1/00; H03F 1/00

(52) U.S. Cl. CPC H04B 1/0078; H03F 1/00; H04B 1/0028; H03F 2200/451

(57) ABSTRACT

An electronic device may include wireless circuitry with delay circuitry coupled to a radio-frequency input of an amplifier over a signal path. Converter circuitry on the signal path may provide a radio-frequency signal to the amplifier based on a baseband signal. An envelope tracking path may couple the delay circuitry to a control input of the amplifier. The delay circuitry may generate a time delay based on a weighting function and a frequency allocation of the radio-frequency signal. The weighting function may be weighted most heavily at a center of the frequency allocation and may decrease as frequency offset increases away from the center frequency. The delay circuitry may apply the time delay between the signal path and the envelope tracking path. The time delay may configure the power amplifier to exhibit optimal radio-frequency performance even when the bandwidth of the frequency allocation is large.

### FIELD

This disclosure relates generally to electronic devices, including electronic devices with wireless circuitry.

### BACKGROUND

Electronic devices can be provided with wireless communications capabilities. An electronic device with wireless communications capabilities has wireless circuitry with one or more antennas. Wireless transceiver circuitry in the wireless circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. A radio-frequency power amplifier can receive a radio-frequency signal and a control signal. If care is not taken, the radio-frequency signal and the control signal arriving at the power amplifier may be temporally misaligned, which can degrade the radio-frequency performance of the power amplifier.

### SUMMARY

An electronic device may include wireless circuitry. The wireless circuitry may include a transmit path. The transmit path may include processing circuitry, delay circuitry, and a power amplifier. An output of the power amplifier may be coupled to an antenna. The delay circuitry may be communicatively coupled to a radio-frequency input of the power amplifier over a signal path. Converter circuitry may be disposed on the signal path. An envelope tracking path containing envelope tracking circuitry may be coupled between the delay circuitry and a power supply input of the power amplifier.

The processing circuitry may transmit a baseband signal to the delay circuitry. The converter circuitry may convert the baseband signal to an analog radio-frequency signal within a corresponding frequency allocation. The power amplifier may amplify the radio-frequency signal. The envelope tracking circuitry may dynamically generate a power supply voltage that is provided to the power supply input of the power amplifier based on an envelope of the baseband signal. The delay circuitry may generate a time delay based on a weighting function and the frequency allocation. The weighting function may be weighted most heavily at a center frequency of the frequency allocation. The weighting function may decrease as frequency offset away from the center frequency increases. The delay circuitry may apply the time delay between the signal path and the envelope tracking path. The time delay may configure the power amplifier to exhibit optimal radio-frequency performance even when the bandwidth of the frequency allocation is large.

An aspect of the disclosure provides wireless circuitry. The wireless circuitry can include a radio-frequency amplifier configured to output a radio-frequency signal. The wireless circuitry can include delay circuitry communicatively coupled to a radio-frequency input of the radio-frequency amplifier over a signal path. The wireless circuitry can include an envelope tracking path coupled between the delay circuitry and a control input of the radio-frequency amplifier, wherein the delay circuitry is configured to apply a time delay between the signal path and the envelope tracking path that is weighted by different amounts across a frequency allocation of the radio-frequency signal.

An aspect of the disclosure provides a method of transmitting a radio-frequency signal within a frequency allocation. The method can include amplifying, using an amplifier, the radio-frequency signal based on a power supply voltage received at a power supply terminal of the amplifier. The method can include generating, using delay circuitry, a time delay based on a weighting function, wherein the weighting function is weighted more heavily at a center frequency of the frequency allocation than at a non-zero frequency offset from the center frequency, the non-zero frequency offset being within the frequency allocation. The method can include adjusting, using envelope tracking circuitry, the power supply voltage based on an envelope of a baseband signal associated with the radio-frequency signal. The method can include causing, using the delay circuitry, the time delay to be imparted to the baseband signal or the power supply voltage.

An aspect of the disclosure provides an electronic device. The electronic device can include an antenna. The electronic device can include processing circuitry configured to output a baseband signal. The electronic device can include converter circuitry coupled between the processing circuitry and the antenna and configured to generate a radio-frequency signal within a frequency allocation based on the baseband signal. The electronic device can include a power amplifier coupled between the converter circuitry and the antenna and configured to amplify the radio-frequency signal based on a power supply voltage. The electronic device can include delay circuitry communicatively coupled to a radio-frequency input of the power amplifier. The electronic device can include envelope tracking circuitry coupled between the delay circuitry and a power supply input of the power amplifier. The delay circuitry can be configured to generate a delay value based on a weighted average of a set of predetermined delay values, the weighted average exhibiting a weighting that decreases as a frequency offset from a center frequency of the frequency allocation increases. The delay circuitry can be configured to cause the power supply voltage or the baseband signal to be delayed by the delay value.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of illustrative transmit circuitry configured to perform a weighted delay between an input signal and a power supply voltage of a radio-frequency amplifier in accordance with some embodiments.

FIG. 4 is a flow chart of illustrative operations involved in transmitting radio-frequency signals using transmit circuitry of the type shown in FIG. 3 in accordance with some embodiments.

FIG. 5 is a plot of different illustrative weighting functions that may be used to generate a weighted delay between an input signal and a power supply voltage of a radio-frequency amplifier in accordance with some embodiments.

FIG. 6 is a plot showing how an illustrative weighted delay may differ from an unweighted average of a predetermined set of calibration data across a frequency allocation of a radio-frequency signal in accordance with some embodiments.

FIG. 7 is a plot showing how application of an illustrative weighted delay between an input signal and a power supply voltage of a radio-frequency amplifier may minimize adjacent channel leakage ratio of the radio-frequency amplifier in accordance with some embodiments.

### DETAILED DESCRIPTION

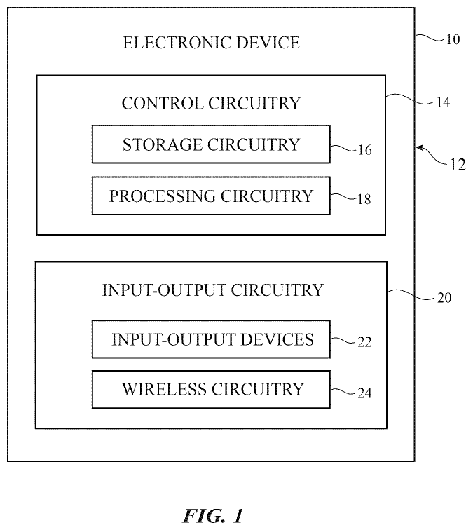

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), satellite communications (satcom) protocols, antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1(FR1 ) bands below 10 GHz, 5G New Radio Frequency Range 2(FR2 ) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, satellite communications (satcom) bands (e.g., an IEEE C band (4-8 GHz), S band (2-4 GHz), L band (1-2 GHz), X band (8-12 GHz), W band (75-110 GHz), V band (40-75 GHz), K band (18-27 GHz), Kₐ band (26.5-40 GHz), Kᵤ band (12-18 GHz), etc.), unlicensed bands, communications bands under the family of 3GPP wireless communications standards, communications bands under the IEEE 802.XX family of standards, and/or any other desired frequency bands of interest.

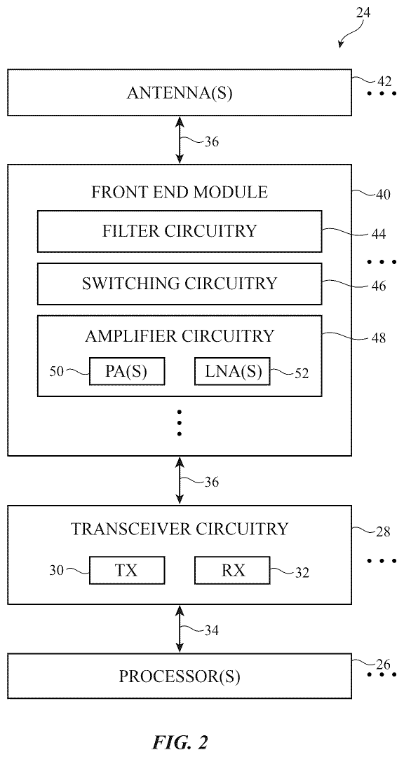

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1(FR1 ) bands below 10 GHz, 5G New Radio Frequency Range 2(FR2 ) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PAs) 50 in the transmit (uplink) path. A power amplifier 50 (sometimes referred to as a radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

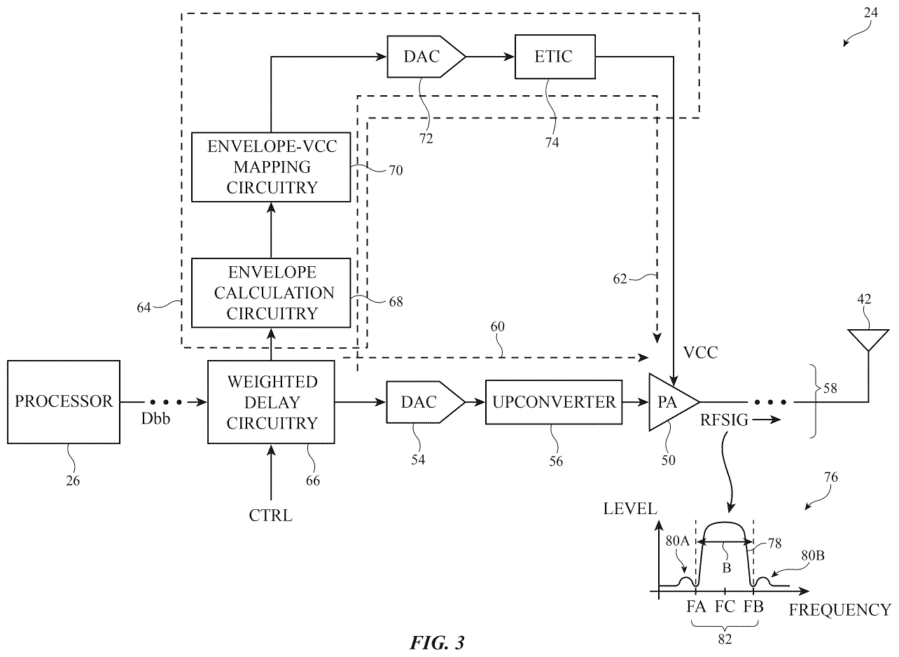

FIG. 3 is a diagram of an illustrative transmit path 58 of wireless circuitry 24. Transmit path 58 is sometimes also referred to herein as transmit chain 58 or transmit circuitry 58. As shown in FIG. 3, wireless circuitry 24 may include processing circuitry such as one or more processors 26, digital-to-analog converter (DAC) circuitry such as DAC 54, upconversion circuitry such as upconverter 56 (e.g., one or more mixers), radio-frequency amplifier circuitry such as radio-frequency amplifier 50 (e.g., a power amplifier), and an antenna 42 configured to radiate radio-frequency signals output by amplifier 50. Additional components (not shown) may also be disposed at different locations along transmit path 58 if desired.

Amplifier 50 may be disposed on FEM 40 or in transceiver circuitry 28 of FIG. 2. Processor(s) 26 may represent one or more processors such as a baseband processor, an application processor, a digital signal processor, a microcontroller, a microprocessor, a central processing unit (CPU), a programmable device, a combination of these circuits, and/or one or more processors within circuitry 18 of FIG. 1. Processor(s) 26 may be configured to generate a digital baseband signal Dbb (e.g., a stream of digital data bits at baseband). Signal Dbb is sometimes referred to as a digital signal or a transmit signal. As examples, the signal Dbb generated by processor(s) 26 may include in-phase (I) and quadrature-phase (Q) signals, radius and phase signals, a vector input, or other digitally coded signals.

DAC 54 may convert signal Dbb from a digital signal into an analog signal (e.g., from the digital domain to the analog domain). Upconverter 56 may upconvert (modulate) the signal from baseband to radio-frequencies. Amplifier 50 may amplify the upconverted signal as radio-frequency signal RFSIG. Antenna 42 may radiate radio-frequency signal RFSIG. DAC 54 may be coupled between processor 26 and upconverter 56, may be coupled between upconverter 56 and amplifier 50 or, if desired, upconverter 56 and DAC 54 may be integrated into a single radio-frequency converter block (e.g., an RF DAC) that performs conversion both from the digital domain to the analog domain and from baseband to radio frequencies. If desired, DAC 54, upconverter 56, and/or an RF DAC may include multiple different cells (e.g., DAC cells, RF DAC cells, etc.) that operate on the signals conveyed via transmit path 58. The input of amplifier 50 configured to receive radio-frequency signals from upconverter 56 is also referred to or defined herein as a radio-frequency input (port) of amplifier 50. Radio frequencies can range from a few kHz to tens of THz. Amplifier 50 may amplify signals on transmit path 58 using a power supply voltage VCC (e.g., while powered or biased by power supply voltage VCC).

Wireless circuitry 24 may also include an envelope tracking (ET) subsystem such as envelope tracking circuitry 64. Envelope tracking circuitry 64 may be coupled between a node on transmit path 58 between processor 26 and DAC 54 and a power supply or bias input, terminal, or port of amplifier 50. Envelope tracking circuitry 64 may receive signal Dbb from transmit path 58 and may continuously adjust or vary power supply voltage VCC to ensure that amplifier 50 is always operating at peak efficiency. Envelope tracking circuitry 64 may, for example, generate and adjust power supply voltage VCC based on the envelope of signal Dbb over time (e.g., envelope tracking circuitry 64 may dynamically tune the amplifier power supply voltage based on the envelope of signal Dbb).

Envelope tracking circuitry 64 may, for example, include envelope calculation circuitry 68, envelope-VCC mapping circuitry 70, one or more DACs such as DAC 72, and envelope tracking integrated circuit (ETIC) 74. The input of envelope calculation circuitry 68 may be coupled to a node on transmit path 58 between processor 26 and DAC 54. Envelope-VCC mapping circuitry 70 may be coupled in series between the output of envelope calculation circuitry 68 and the input of DAC 72. DAC 72 may be coupled in series between the output of envelope-VCC mapping circuitry 70 and the input of ETIC 74. ETIC 74 may have an output coupled to a power supply terminal, input, or port of amplifier 50 (e.g., over a corresponding power supply line). DAC 72 may, if desired, include a set of separate DACs or DAC cells. DAC 72 is sometimes also referred to herein as an ET DAC 72 or converter block 72.

Envelope calculation circuitry 68 may, for example, calculate, extract, recover, and/or identify an envelope of the signal Dbb on transmit path 58. If desired, envelope calculation circuitry 68 may convert the envelope from an I/Q space (e.g., when signal Dbb is an I/Q signal) into corresponding real values. Envelope-VCC mapping circuitry 70 may map the real-valued envelope output by envelope calculation circuitry 68 into a signal that drives DAC 72. DAC 72 may convert the signal from the digital domain to the analog domain. ETIC 74 may generate power supply voltage VCC based on the signal received from DAC 72. ETIC 74 may, for example, change the magnitude of power supply voltage VCC as the signal received from DAC 72 changes over time (e.g., as the magnitude of the envelope of signal Dbb changes over time). This is illustrative and non-limiting and, in general, envelope tracking circuitry 64 may include any desired components or circuits.

Power supply voltage VCC is fed to a power supply terminal of amplifier 50. The power supply terminal of amplifier 50 that receives VCC from envelope tracking circuitry 64 is sometimes also referred to as a control input of amplifier 50. Power supply voltage VCC can therefore sometimes be referred to and defined herein as a control signal (e.g., a tunable/adjustable power supply voltage or control signal). Thus, envelope tracking circuitry 64 can sometimes be referred to generally as a control signal generator. Control signals provided to the control input of amplifier 50 may include a power supply voltage, load-line control signals (e.g., for controlling the amplifier's load-line modulation while keeping supply voltage constant), etc. Any operations described herein as being performed on power supply voltages provided to the power amplifier can also be performed on other types of control signals provided to the control input of the power amplifier (e.g., by envelope tracking circuitry or other control circuitry). While referred to herein as envelope tracking circuitry, envelope tracking circuitry 64 need not perform envelope tracking for the amplifier and may, if desired, be used to control load-line modulation of the amplifier (e.g., envelope tracking circuitry 64 may also be referred to as load-line modulation control circuitry 64 or simply as amplifier control circuitry 64).

Plot 76 of FIG. 3 illustrates the signal level (magnitude) of the radio-frequency signal RFSIG output by amplifier 50 as a function of frequency. As shown in plot 76, radio-frequency signal RFSIG may be transmitted at frequencies within a corresponding frequency allocation 82 (e.g., as scheduled for device 10 by the corresponding wireless network, an application running on device 10, etc.). Frequency allocation 82 may span one or more continuous resource blocks, resource elements, sub-channels, and/or another set of frequency spectrum/resources, and is sometimes also referred to herein as frequency range 82 (e.g., a continuous set of resource blocks/elements, a frequency channel, some or all of frequency/communications band, etc.). Frequency allocation 82 may be defined by its center frequency FC and a corresponding bandwidth B around center frequency FC (e.g., where half of bandwidth B is below center frequency FC and the other half of bandwidth B is above center frequency FC). Frequency allocation 82 may extend from a lower limit FA to an upper limit FB. Bandwidth B may extend from lower limit FA to upper limit FB. Center frequency FC may be halfway between lower limit FA and upper limit FB.

Radio-frequency signal RFSIG may exhibit a peak 78 within frequency allocation 82 (e.g., extending across bandwidth B). If care is not taken, amplifier 50 may impart a non-zero amount of adjacent channel leakage to radio-frequency signal RFSIG, shown by one or more peaks 80 outside of frequency allocation 82 (e.g., a first peak 80A below lower limit FA and/or a second peak 80B higher than upper limit FB). The amount of adjacent channel leakage imparted by amplifier 50 may be characterized by a wireless performance metric such as adjacent channel leakage ratio (ACLR). In practice, higher power supply voltages VCC may help to increase the radio-frequency performance of amplifier 50 (e.g., decreasing ACLR, up to a certain limit), whereas lower power supply voltages VCC may help to reduce power consumption in device 10. Suitable selection of power supply voltage VCC may serve to balance a reduction in power consumption with wireless performance (e.g., a reduction in ACLR and thus out-of-channel peaks 80 with a reduction in power consumption).

Envelope tracking circuitry 64 may operably couple the node between DAC 54 and processor 26 on transmit path 58 and the power supply input terminal of amplifier 50 over a first signal path such as signal path 62, which is sometimes also referred to herein as ET path 62. The node may also be communicatively coupled to the radio-frequency input of amplifier 50 over a second signal path such as signal path 60, which is sometimes also referred to herein as transmit path 60 or forward path 60. DAC 54 and upconverter 56 may be disposed on forward path 60.

Ideally, envelope tracking circuitry 64 tunes supply voltage VCC by perfectly tracking the envelope of the radio-frequency signal arriving at the radio-frequency input of amplifier 50 over time. To accomplish this, delay circuitry may be disposed on transmit path 58 between processor 26 and DAC 54 (e.g., at the node of transmit path 58 that is coupled to the input of envelope tracking circuitry 64). The delay circuitry may apply time delays to signals on one or both of paths 60 and 62 to help ensure that the timing of supply voltage VCC is synchronized to the envelope of the radio-frequency signal arriving at the radio-frequency input of amplifier 50.

However, the time alignment requirement between paths 60 and 62 becomes more stringent as the intended bandwidth of radio-frequency signal RFSIG increases. For example, as bandwidth B becomes relatively high (e.g., as the communications capabilities of devices such as device 10 improve over time), it can become more difficult to ensure that signal delay through forward path 60 sufficiently matches the signal delay through ET path 62 in a manner that optimizes the radio-frequency performance of amplifier 50. This is because delay mismatch between paths 60 and 62 (sometimes also referred to herein as ET delay mismatch) exhibits a frequency-selective impact on transmission performance. More particularly, ET delay mismatch near center frequency FC of frequency allocation 82 tends to have a worse impact on ACLR and/or error vector magnitude (EVM) for the radio-frequency signal RFSIG output by amplifier 50 than the same ET delay mismatch closer to the edges of frequency allocation 82. The differential effect of ET delay mismatch across bandwidth B on the radio-frequency performance of amplifier 50 may be negligible when bandwidth B is relatively low. However, the differential effect of ET delay mismatch across bandwidth B on the radio-frequency performance of amplifier 50 becomes non-negligible when bandwidth B is relatively wide (e.g., around 50-100 MHz or higher).

To help mitigate these issues and to ensure that amplifier 50 exhibits sufficient levels of radio-frequency performance (e.g., ACLR, EVM, etc.) even as the bandwidth B of frequency allocation 82 becomes relatively large (e.g., 100 MHz), transmit path 58 may include weighted delay circuitry such as weighted delay circuitry 54 at the node between processor 26 and DAC 54. Weighted delay circuitry 66 may be operably coupled to the input of envelope tracking circuitry 64 and/or the input of DAC 54. Weighted delay circuitry 66 may generate and impart a corresponding weighted time delay (sometimes also referred to herein as weighted delay value D_WEIGHT) to the signals on ET path 62 (e.g., to the power supply voltage VCC supplied to the control input of amplifier 50) and/or to the signals on forward path 60 (e.g., to the radio-frequency signal supplied to the radio-frequency input of amplifier 50). The weighted time delay may be a time delay that ensures that amplifier 50 exhibits a sufficient or optimal level of radio-frequency performance (e.g., minimal ACLR) given the current frequency allocation 82 of radio-frequency signal RFSIG.

The weighted time delay may, for example, be generated using a weighting function that decreases as frequency moves away from the center frequency FC of frequency allocation 82 (e.g., the weighting function may be a weighted linear combination that weights a predetermined set of calibrated values at one or more frequencies closer to center frequency FC more heavily than at frequencies farther from center frequency FC and/or closer to limits FA/FB). Weighted delay circuitry 66 may, for example, generate the weighted time delay as a weighted average or linear combination of a predetermined set of calibrated values, where the weights of the weighted average or linear combination are given by the weighting function. The weights of the weighted average or linear combination (e.g., the weighting function) may decrease as the magnitude of frequency offset relative to center frequency FC increases.

Once weighted delay circuitry 66 has generated a weighted delay value, delay circuitry 66 may provide the weighted delay value to envelope tracking circuitry 64 to control envelope tracking circuitry 64 to apply the weighted delay value to the power supply voltage VCC supplied to amplifier 50. Alternatively, weighted delay circuitry 66 may directly impart or apply the weighted delay value to the signal Dbb supplied to the input of DAC 54. Alternatively, weighted delay circuitry 66 may control envelope tracking circuitry 64 to impart a first intermediate timing delay to power supply voltage VCC and may directly impart a second intermediate timing delay to the signal Dbb supplied to DAC 54 (e.g., such that the difference between the first and second intermediate timing delays is equal to the weighted delay value). Put differently, weighted delay circuitry 66 may control the relative timing delay between paths 60 and 62 based on the current frequency allocation 82 of radio-frequency signal RFSIG in a manner that weights frequencies closer to center frequency FC more heavily than frequencies farther from center frequency FC, which may increase the radio-frequency performance of amplifier 50 given frequency allocation 82.

Weighted delay circuitry 66 may, if desired, receive a control signal CTRL (e.g., from processor 26 or other control circuitry) that controls the weighting performed by weighted delay circuitry 66 in generating the weighted delay value to be applied between paths 60 and 62. Control signal CTRL may, for example, control weighted delay circuitry 66 to generate different weighted delay values using different weighting functions as frequency allocation 82 (e.g., center frequency FC and/or bandwidth B) change over time (e.g., based on the communications schedule for device 10). Weighted delay circuitry 66 is sometimes also referred to herein as weighted ET delay circuitry 66, ET delay generation circuitry 66, delay circuitry 66, weighted averaging circuitry 66, weighting circuitry 66, frequency-based weighted delay circuitry 66, or frequency-based weighting circuitry 66. Weighted delay circuitry 66 may include digital calculation logic (e.g., circuitry that calculates weighted linear combinations of a predetermined set of calibrated data using weights given by a weighting function to produce weighted delay values). If desired, weighted delay circuitry 66 may also include any desired digital delay circuitry (e.g., latches, registers, inverters, signal lines, transistor-based delay circuits, etc.) that imparts the generated weighted delay value to signals on forward path 60 or ET path 62.

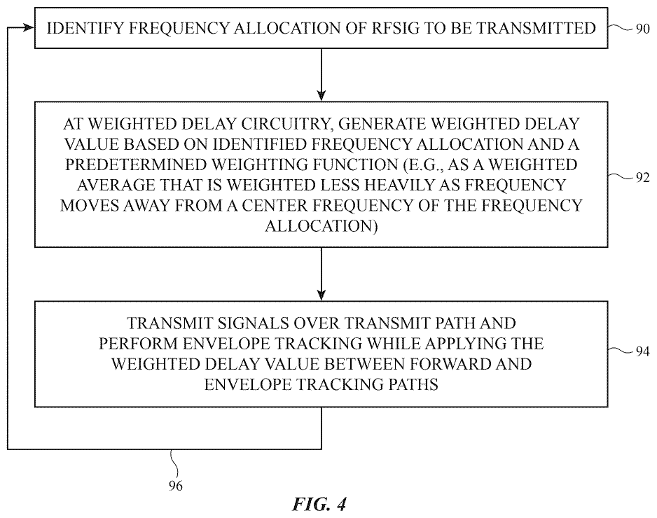

FIG. 4 is a flow chart of illustrative operations involved in transmitting radio-frequency signals RFSIG using transmit path 58 and envelope tracking circuitry 64 of FIG. 3. The operations of FIG. 4 may be performed while device 10 is operated in the field (e.g., by an end user) after device 10 has been assembled, manufactured, tested, and/or calibrated (e.g., in factory).

At operation 90, control circuitry 14 (FIG. 1) may identify the frequency allocation 82 of the radio-frequency signal RFSIG to be transmitted over transmit path 58. This may include identification of center frequency FC, bandwidth B, upper limit FB, and/or lower limit FA. Frequency allocation 82 may be determined by a communication schedule for device 10 (e.g., as maintained by a wireless network), by one or more applications running on device 10, by one or more communications requirements imposed on device 10, etc.

At operation 92, weighted delay circuitry 66 may generate a weighted delay value D_WEIGHT based on the identified frequency allocation 82 (e.g., as identified in the control signal CTRL provided to weighted delay circuitry 66) and a predetermined weighting function (e.g., from a list of weighting functions stored at weighted delay circuitry 66). Weighted delay circuitry 66 may, for example, generate weighted delay value D_WEIGHT by applying the predetermined weighting function on a predetermined set of calibrated values stored at weighted delay circuitry 66 (e.g., by averaging the set of calibrated values using weighting, weight values, or weight densities that are given by the predetermined weighting function and/or by inputting the predetermined set of calibrated values to the weighting function).

The weighting function may be stored at weighted delay circuitry 66 during calibration of device 10 (e.g., in factory) or may be received or updated after device 10 has begun operating in the field. The weighting function may exhibit a maximum (e.g., a maximum weight density) at center frequency FC and may exhibit minima (e.g., minimum weight densities) at upper limit FB and lower limit FA of frequency allocation 82 (e.g., the weighting function and thus a weighted average computed using the weighting function may be weighted most heavily at center frequency FC and may be weighted least heavily at limits FA and FB). The predetermined weighting function (e.g., weight density) may, for example, decrease as frequency moves away from center frequency FC to limits FA and FB (e.g., the weight density may decrease as the magnitude of frequency offset away from center frequency FC increases). Put differently, weighted delay circuitry 66 may generate weighted delay value D_WEIGHT by performing a weighted average or linear combination of values over the frequencies within frequency allocation 82 (e.g., by performing the weighting function on the predetermined set of calibrated values within frequency allocation 82), where the weights or weighting of the values decreases as the magnitude of frequency offset away from center frequency FC increases (e.g., from a maximum weighting at center frequency FC to minimum weighting at limits FA/FB).

At operation 94, transmit path 58 may transmit radio-frequency signals RFSIG. Processor 26 may transmit signal Dbb to weighted delay circuitry 66, which passes signal Dbb to DAC 54. DAC 54 may convert signal Dbb into an analog signal and upconverter 56 may upconvert the signal to a radio-frequency signal. Power amplifier 50 may amplify the radio-frequency signal to produce radio-frequency signal RFSIG, which is radiated by antenna 42. At the same time, envelope tracking circuitry 64 may generate and provide power supply voltage VCC to the control input of amplifier 50 based on the signal Dbb output by processor 26.

Weighted delay circuitry 66 may control envelope tracking circuitry 64 to provide power supply voltage VCC to the control input of amplifier 50 with timing that is delayed by weighted delay value D_WEIGHT (e.g., weighted delay circuitry 66 may control envelope tracking circuitry 64 to impart or apply weighted delay value D_WEIGHT to the power supply voltage VCC supplied to amplifier 50 over time). Alternatively, weighted delay circuitry 16 may impart weighted delay value D_WEIGHT to the signal Dbb transmitted to DAC 54. Alternatively, weighted delay circuitry 66 may control envelope tracking circuitry 64 to impart a first intermediate delay value to power supply voltage VCC and may impart a second intermediate delay value to the signal Dbb supplied to DAC 54 (e.g., where the first and second intermediate delays effectively produce a differential delay between paths 62 and 60 equal to weighted delay value D_WEIGHT). This help to may ensure that amplifier 50 exhibits optimal radio-frequency performance (e.g., minimal ACLR) given the current frequency allocation 82 of radio-frequency signal RFSIG, despite radio-frequency signal RFSIG exhibiting a relatively wide bandwidth B. Processing may then loop back to operation 90 via path 96 and weighted delay circuitry 66 may change the magnitude of weighted delay value D_WEIGHT as the frequency allocation 82 of radio-frequency signal RFSIG changes over time.

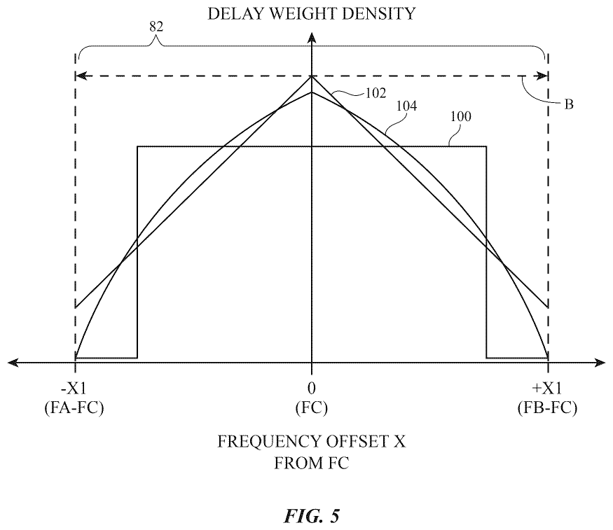

FIG. 5 illustrates three exemplary weighting functions that may be used by weighted delay circuitry 66 to generate weighted delay value D_WEIGHT. The horizontal axis of FIG. 5 plots frequency as a frequency offset X, which characterizes frequency offset away from center the frequency FC of frequency allocation 82, from a first frequency offset −X1 (e.g., corresponding to the lower limit FA of frequency allocation 82 and given by FA-FC) to a second frequency offset +X1 (e.g., corresponding to the upper limit FB of frequency allocation 82 and given by FB-FC). The vertical axis of FIG. 5 plots weight density (e.g., the amount of weighting applied at different frequency offsets from center frequency FC when applying the weighting function to the predetermined set of calibration values).

In general, weighted delay circuitry 66 may generate weighted delay value D_WEIGHT using any desired weighting function that decreases as frequency offset X from center frequency FC increases (e.g., where the weighting function exhibits maximum weight density at center frequency FC and minimum weight density at limits FA/FB). Put differently, weighted delay circuitry 66 may generate weighted delay value D_WEIGHT using any desired weighting function that weights less heavily (or that includes decreasing weights) as frequency moves away from center frequency FC (e.g., in both the positive and negative direction). If desired, the weighting function may be symmetric about center frequency FC. Alternatively, the weighting function may be asymmetric about center frequency FC. The weighting function may be smoothly varying (e.g., continuous and differentiable as frequency offset X increases from center frequency FC to −X1 or +X1) or discretely varying (e.g., discontinuous or non-differentiable as frequency offset X increases in one or more steps from center frequency FC to −X1 or +X1). Weighted delay circuitry 66 may generate weighted delay value D_WEIGHT by applying the corresponding weighting function to a predetermined set of calibration values stored at weighted delay circuitry 66 (e.g., by inputting the predetermined set of calibration values to the weighting function, by performing the weighting function on the predetermined set of calibration values, by generating a linear combination or weighted average of the predetermined set of calibration having weights given by the weighting function, etc.).

Curve 100 illustrates a first example of a weighting function that may be implemented by weighted delay circuitry 66. Curve 100 may represent a rectangular weighting function (e.g., a step function) that exhibits a constant maximum weight density within a subrange of frequency allocation 82 centered at center frequency FC and that drops or steps down to a constant minimum weight density or zero weight density outside of the subrange, adjacent frequency offsets −X1 and +X1 (e.g., at points that are separated from frequency offsets −X1 and +X1 by 5-20% of the bandwidth B of frequency allocation 82).

Curve 102 illustrates a second example of a weighting function that may be implemented by weighted delay circuitry 66. Curve 102 may represent a linear weighting function that linearly decreases from a maximum weight density at center frequency FC to a minimum weight density at offsets +X1 and −X1, as the magnitude |X| of frequency offset X increases away from center frequency FC (e.g., curve 102 may linearly increase from offset −X1 to center frequency FC and may linearly decrease from center frequency FC to offset +X1).

Curve 104 illustrates a third example of a weighting function that may be implemented by weighted delay circuitry 66. Curve 104 may represent an exponential weighting function that exponentially decreases from a maximum weight density at center frequency FC to a minimum weight density at offsets +X1 and −X1, as the magnitude |X| of frequency offset X increases away from center frequency FC (e.g., curve 104 may increase from offset −X1 to center frequency FC and may decrease from center frequency FC to offset +X1 non-linearly).

The example of FIG. 5 is illustrative and non-limiting. In general, weighted delay circuitry 66 may apply any desired weighting function that decreases as the magnitude |X| of frequency offset X increases away from center frequency FC of frequency allocation 82. Weighted delay circuitry 66 may generate weighted delay value D_WEIGHT by applying one of the weighting functions (e.g., curve 100, curve 102, curve 104, or another weighting function) to a predetermined set of calibrated values spanning frequency allocation 82 (e.g., while processing operation 94 of FIG. 4). The predetermined set of calibrated values may, for example, be generated during testing and calibration of device 10 or similar devices in factory (e.g., prior to shipping device 10 to an end user). The predetermined set of calibrated values may, for example, include a set of delay values between paths 60 and 62 that were detected during factory testing/calibration across different frequencies (e.g., using transmitted test signals swept across frequency and active measurements of the output of amplifier 50 using laboratory-grade test equipment) to have maximized the radio-frequency performance of amplifier 50 (e.g., minimizing the ACLR of amplifier 50).

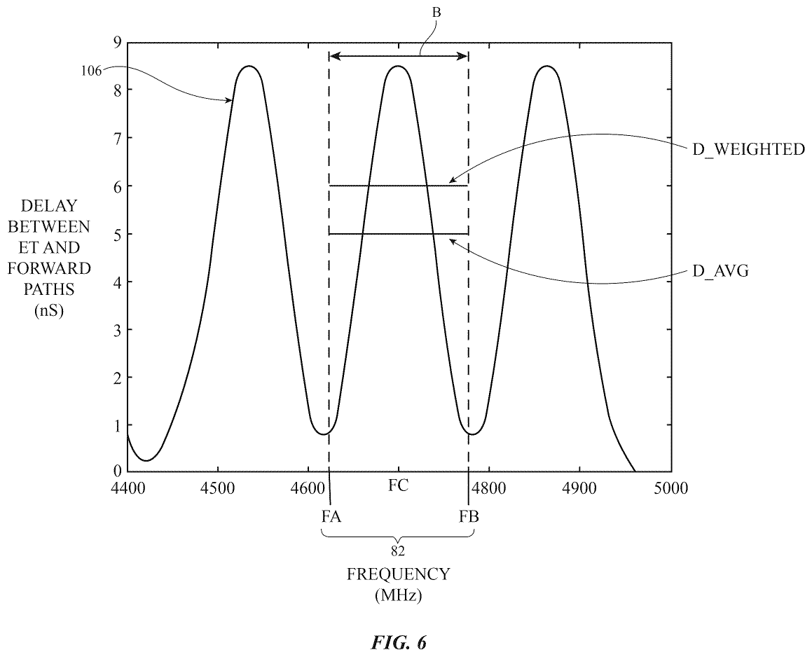

Curve 106 of FIG. 6 illustrates an example of one such predetermined set of calibrated values that may be stored at weighted delay circuitry 66 for use in generating weighted delay value D_WEIGHT. Curve 106 may, for example, represent relative timing delays between paths 60 and 62 that were found during factory calibration of device 10 to optimize radio-frequency performance (e.g., minimizing ACLR and/or EVM) as a function of frequency of the radio-frequency signal RFSIG transmitted over signal path 58.

In some implementations, delay circuitry between processor 26 and DAC 54 applies a delay value D_AVG to path 60 or path 62 that is generated by performing a simple unweighted average of the predetermined set of calibrated values across frequency allocation 82 (e.g., delay value D_AVG may represent an average of the values of curve 106 from lower limit FA to upper limit FB, where each frequency across frequency allocation 82 from lower limit FA to upper limit FB is weighted equally). However, utilizing delay value D_AVG between paths 60 and 62 may cause amplifier 50 to exhibit insufficient levels of radio-frequency performance (e.g., an amount of ACLR that exceeds a threshold), particularly when bandwidth B is relatively large (e.g., 50-100 MHz or higher).

On the other hand, unlike delay value D_AVG, weighted delay value D_WEIGHTED is generated by performing a weighted average of the values of curve 106 from lower limit FA to upper limit FB that exhibits unequal weighting across frequency allocation 82 (e.g., by performing a linear combination of the predetermined set of calibrated values within frequency allocation 82 but with non-equal weighting as frequency varies from lower limit FA to upper limit FB). By applying a weighting function that weights the predetermined set of calibrated values (e.g., the values of curve 106) more heavily at frequencies closer to center frequency FC than at frequencies farther away from center frequency FC (e.g., using the weighting functions illustrated by curves 100-104 of FIG. 5 or similar weighting functions that decrease as the magnitude |X| of frequency offset X increases), weighted delay circuitry 66 may impart a weighted delay value D_WEIGHTED between paths 60 and 62 that causes amplifier 50 to exhibit sufficient levels of radio-frequency performance (e.g., less than a threshold amount of ACLR) even when bandwidth B is relatively large.

The increased weighting at center frequency FC and at frequencies closer to center frequency FC and the decreased weighting at limits FA/FB and at frequencies closer to limits FA/FB as determined by the weighting function may, for example, cause weighted delay value D_WEIGHTED to be different than (e.g., greater than) the delay value D_AVG generated by performing an unweighted average of curve 106 over frequency allocation 82. This weighted delay value may cause amplifier 50 to exhibit superior performance (e.g., lower ACLR) than when delay value D_AVG is used, despite bandwidth B being relatively large. The weighted delay value may be updated and optimized as frequency allocation 82 and/or bandwidth B change over time (e.g., given the signal transmission requirements of device 10). The example of FIG. 6 is illustrative and, in practice, curve 106 may have other shapes. Frequency allocation 82 may be over any desired radio frequencies. Bandwidth B may be any desired bandwidth (e.g., 80-100 MHz, 50 -150 MHz, 100-200 MHz, 50 -250 MHz, less than 80 MHz, greater than 100 MHz, greater than 80 MHz, greater than 120 MHz, etc.).

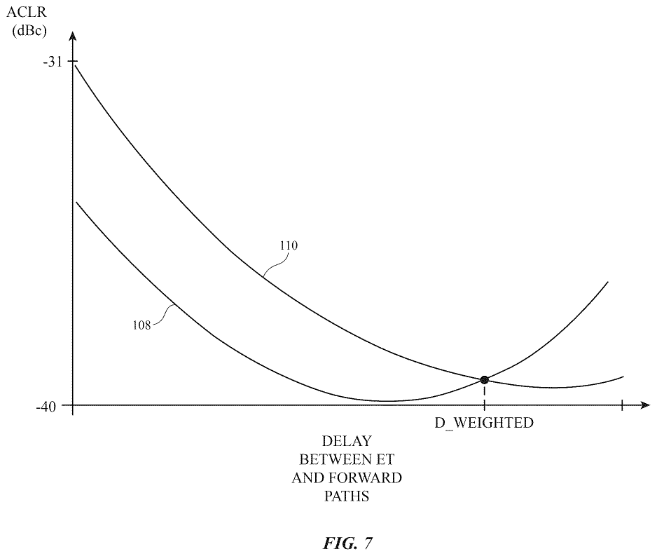

FIG. 7 is a plot illustrating how applying weighted delay value D_WEIGHTED between ET path 62 and forward path 60 may serve to maximize the radio-frequency performance of amplifier 50 while transmitting radio-frequency signals RFSIG with a frequency allocation 82 having bandwidth B. As shown in FIG. 7, curve 110 plots the ACLR of amplifier 50 and radio-frequency signal RFSIG below lower limit FA (e.g., corresponding to the magnitude of peak 80A in plot 76 of FIG. 3) as a function of time delay between ET path 62 and forward path 60. Curve 108 plots the ACLR of amplifier 50 and radio-frequency signal RFSIG above upper limit FB (e.g., corresponding to the magnitude of peak 80B in plot 76 of FIG. 3) as a function of time delay between ET path 62 and forward path 60.

In practice, curves 108 and 110 may have different minima. Weighted delay value D_WEIGHTED may be a delay value corresponding to the intersection of curves 108 and 110. When weighted delay circuitry 66 imparts weighted delay value D_WEIGHTED between paths 60 and 62, amplifier 50 and radio-frequency signal RFSIG may exhibit an optimal reduction in both ACLR below lower limit FA and ACLR above upper limit FB, and thus an optimal overall reduction in ACLR (e.g., even if weighted delay value D_WEIGHTED does not align with the minimum of either of curves 108 and 110). In this way, transmit path 58 may transmit radio-frequency signals while performing envelope tracking with sufficient levels of radio-frequency performance even when bandwidth B is relatively high. Curves 108 and 110 may have other shapes in practice.

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Wireless circuitry comprising:
a radio-frequency amplifier configured to output a radio-frequency signal;
delay circuitry communicatively coupled to a radio-frequency input of the radio-frequency amplifier over a signal path; and
an envelope tracking path coupled between the delay circuitry and a control input of the radio-frequency amplifier, wherein the delay circuitry is configured to apply a time delay between the signal path and the envelope tracking path that is weighted by different amounts across a frequency allocation of the radio-frequency signal.

2. The wireless circuitry of claim 1, wherein the frequency allocation has a center frequency, an upper limit, and a lower limit, and the time delay is weighted more heavily at the center frequency than at the upper limit and the lower limit.

3. The wireless circuitry of claim 2, wherein a weighting of the time delay decreases from the center frequency to the upper limit and decreases from the center frequency to the lower limit.

4. The wireless circuitry of claim 1, further comprising:
control circuitry disposed on the envelope tracking path and configured to generate a control signal that is provided to the control input of the radio-frequency amplifier.

5. The wireless circuitry of claim 4, wherein the delay circuitry is configured to control the control circuitry to apply the time delay to the control signal.

6. The wireless circuitry of claim 4, wherein the control circuitry comprises:
envelope-to-power supply voltage mapping circuitry;
envelope calculation circuitry coupled between the delay circuitry and the envelope-to-power supply voltage mapping circuitry;
an envelope tracking integrated circuit configured to generate the control signal; and
a digital-to-analog converter coupled between the envelope-to-power supply voltage mapping circuitry and the envelope tracking integrated circuit.

7. The wireless circuitry of claim 4, further comprising:
a processor configured to transmit a baseband signal to the delay circuitry; and
a digital-to-analog converter (DAC) disposed on the signal path between the delay circuitry and the radio-frequency amplifier, wherein the delay circuitry is coupled between the processor and the DAC.

8. The wireless circuitry of claim 7, wherein the delay circuitry is configured to apply the time delay to the baseband signal.

9. The wireless circuitry of claim 7, wherein the delay circuitry is configured to impart the baseband signal with a first portion of the time delay and is configured to control the control circuitry to impart the control signal with a second portion of the time delay.

10. The wireless circuitry of claim 7, further comprising:
an upconverter disposed on the signal path between the DAC and the radio-frequency amplifier; and
an antenna communicatively coupled to an output of the radio-frequency amplifier.

11. The wireless circuitry of claim 1, wherein:
the delay circuitry is configured to apply the time delay between the signal path and the envelope tracking path at a first time,
the delay circuitry is further configured to apply an additional time delay between the signal path and the envelope tracking path at a second time different from the first time,
the radio-frequency signal has the frequency allocation at the first time,
the radio-frequency signal has an additional frequency allocation at the second time,
the additional frequency allocation is different from the frequency allocation at the first time, and
the additional time delay is weighted by different amounts across the additional frequency allocation of the radio-frequency signal.

12. The wireless circuitry of claim 1, wherein the delay circuitry is configured to generate the time delay by performing a weighted average, across the frequency allocation, of a predetermined set of time delays as a function of frequency, wherein the weighted average includes weights that vary across the frequency allocation.

13. The wireless circuitry of claim 12, wherein the weights comprise:
a first weight at a center frequency of the frequency allocation, and
a second weight at an additional frequency that is between the center frequency and a boundary of the frequency allocation, the second weight being less than the first weight.

14. A method of transmitting a radio-frequency signal within a frequency allocation, the method comprising:
amplifying, using an amplifier, the radio-frequency signal based on a power supply voltage received at a power supply terminal of the amplifier;
generating, using delay circuitry, a time delay based on a weighting function, wherein the weighting function is weighted more heavily at a center frequency of the frequency allocation than at a non-zero frequency offset from the center frequency, the non-zero frequency offset being within the frequency allocation;
adjusting, using envelope tracking circuitry, the power supply voltage based on an envelope of a baseband signal associated with the radio-frequency signal; and
causing, using the delay circuitry, the time delay to be imparted to the baseband signal or the power supply voltage.

15. The method of claim 14, wherein the weighting function is weighted less heavily as the non-zero frequency offset increases from the center frequency to a boundary of the frequency allocation.

16. The method of claim 15, wherein the weighting function varies smoothly as the non-zero frequency offset increases from the center frequency to the boundary of the frequency allocation.

17. The method of claim 15, wherein the weighting function varies in one or more discrete steps as the non-zero frequency offset increases from the center frequency to the boundary of the frequency allocation.

18. The method of claim 15, wherein the weighting function is symmetric about the center frequency.

19. The method of claim 15, wherein generating the time delay based on the weighting function comprises:
performing a weighted linear combination of a predetermined set of time delays across the frequency allocation, wherein the weighted linear combination comprises a first weight at a center frequency of the frequency allocation and a second weight at a boundary of the frequency allocation, the second weight being less than the first weight.

20. An electronic device comprising:
an antenna;
processing circuitry configured to output a baseband signal;
converter circuitry coupled between the processing circuitry and the antenna and configured to generate a radio-frequency signal within a frequency allocation based on the baseband signal;
a power amplifier coupled between the converter circuitry and the antenna and configured to amplify the radio-frequency signal based on a power supply voltage;
delay circuitry communicatively coupled to a radio-frequency input of the power amplifier; and
envelope tracking circuitry coupled between the delay circuitry and a power supply input of the power amplifier, wherein the delay circuitry is configured to
generate a delay value based on a weighted average of a set of predetermined delay values, the weighted average exhibiting a weighting that decreases as a frequency offset from a center frequency of the frequency allocation increases, and
cause the power supply voltage or the baseband signal to be delayed by the delay value.
